(19) United States
(12) Patent Application Publication
(10) Pub. No.: US 2026/0079193 A1
(43) Pub. Date: Mar. 19, 2026

(54) Directional Fault Locating in a Power Network

(71) Applicant: Zaphiro Technologies SA, Renens (CH)

(72) Inventors: Lorenzo Zanni, Renens (CH); Mayank Nagendran, Lausanne (CH); Paolo Romano, Lausanne (CH)

(21) Appl. No.: 19/490,413

(22) PCT Filed: Jun. 9, 2023
(86) PCT No.: PCT/EP2023/065547

§ 371 Date: Dec. 5, 2025

(51) Int. Cl. G01R 31/08

(52) U.S. Cl. CPC G01R 31/088; G01R 31/086

(57) ABSTRACT

A fault location determining arrangement in a power network obtains a voltage based on processing of a voltage measurement VM made by a measurement collecting unit in the network node that is associated with a measurement point at which the measurement is made, obtains a number of currents based on processing of current measurements made by measurement collecting units in network nodes associated with measurement points at which the measurements are made, where the current measurements are made at the same point in time as the voltage measurement, compares each current with a current threshold, determines a number of phase angles based on the voltage and all currents, each phase angle being a phase angle between the voltage and a different current, analyses, for each current, whether it crosses the threshold and the phase angle to the voltage and determines, based on the analysis, if a fault F has occurred in the power network and an area in which the fault has occurred.

### TECHNICAL FIELD

The present disclosure relates to a method, fault location determining arrangement, computer program and computer program product for determining the location of a fault in a power network as well as to a power network comprising such a fault location determining arrangement.

### BACKGROUND

The determination of fault locations is an important aspect in power networks, such as in medium voltage power distribution networks. This allows an area where the fault occurs to be disconnected for protective measures.

One way of detecting a fault location is disclosed in EP 2741390, where a phase displacement between a zero-sequence voltage and the derivate of a zero-sequence current is used. The voltage and current of a measurement point is thus used to determine a fault location. The number of measurement points in a power network may be high. For instance, it is not uncommon with more than 200 measurement points. This means that many voltage and current measurement units are often needed.

There is therefore a need for improving on this situation, i.e to reduce the number of required measurement units.

### SUMMARY

One objective is to enable a reduction of the number of measurement units required in a power network.

This objective is achieved by a method for determining the location of a fault in a power network, the power network comprising a number of measurement points, a number of network nodes and a number of measurement collecting units, each being provided in a network node, being associated with at least one measurement point at the network node and collecting measurements from the measurement point, the power network being divided into different areas bounded by measurement points from which the measurement collecting units collect measurements, the method being performed in a fault location determining function implemented by a fault location determining arrangement and comprising:
obtaining a voltage based on a voltage measurement made at a measurement point, which voltage is obtained based on processing of the voltage measurement made by a measurement collecting unit in the network node associated with the measurement point,
obtaining a number of currents based on current measurements made at a plurality of measurement points, which currents are obtained based on processing of the current measurements made by measurement collecting units in network nodes associated with the measurement points and where the current measurements have been made at the same point in time as the voltage measurement,
comparing each current with a current threshold,
determining a number of phase angles based on the voltage and all of the currents, each phase angle being a phase angle between the voltage and a different current,
analysing, for each current, whether it crosses the threshold or not and the phase angle to the voltage, and
determining, based on the analysis, if a fault has occurred in the power network and if a fault has occurred also the area in which it has occurred.

The objective is also achieved through a fault location determining arrangement for determining the location of a fault in a power network comprising a number of measurement points, a number of network nodes and a number of measurement collecting units, each being provided in a network node, being associated with at least one measurement point at the network node and collecting measurements from the measurement point, the power network being divided into different areas bounded by measurement points from which the measurement collecting units collect measurements, the fault location determining arrangement comprising one or more processors operative to implement a fault location determining function comprising:
obtaining a voltage based on a voltage measurement made at a measurement point, which voltage is obtained based on processing of the voltage measurement made by a measurement collecting unit in the network node associated with the measurement point,
obtaining a number of currents based on current measurements made at a plurality of measurement points, which currents are obtained based on processing of the current measurements made by measurement collecting units in network nodes associated with the measurement points and where the current measurements have been made at the same point in time as the voltage measurement,
comparing each current with a current threshold,
determining a number of phase angles α based on the voltage and all of the currents, each phase angle being a phase angle between the voltage and a different current,
analysing, for each current, whether it crosses the threshold or not and the phase angle to the voltage, and
determining, based on the analysis, if a fault has occurred in the power network and if a fault has occurred also the area in which it has occurred.

The objective is also achieved through a computer program for determining the location of a fault in a power network, the power network comprising
a number of measurement points, a number of network nodes and a number of measurement collecting units, each being provided in a network node, being associated with at least one measurement point at the network node and collecting measurements from the measurement point, the power network being divided into different areas bounded by measurement points from which the measurement collecting units collect measurements,
the computer program comprising computer program code which when run by one or more processors of a fault location determining arrangement causes the fault location determining arrangement to implement a fault location determining function comprising:
   obtaining a voltage based on a voltage measurement made at a measurement point, which voltage is obtained based on processing of the voltage measurement made by a measurement collecting unit in the network node associated with the measurement point,
   obtaining a number of currents based on current measurements made at a plurality of measurement points, which currents are obtained based on processing of the current measurements made by measurement collecting units in network nodes associated with the measurement points and where the current measurements have been made at the same point in time as the voltage measurement,
   comparing each current with a current threshold,
   determining a number of phase angles based on the voltage and all of the currents, each phase angle being a phase angle between the voltage and a different current,
   analysing, for each current, whether it crosses the threshold or not and the phase angle to the voltage, and
   determining, based on the analysis, if a fault has occurred in the power network and if a fault has occurred also the area in which it has occurred.

The objective is also achieved by a computer program product for determining the location of a fault in a power network, the computer program product comprising one or more computer readable storage media with computer program code according to the third aspect.

The objective is also achieved by a power network comprising a fault location determining arrangement, a number of measurement points, a number of network nodes and a number of measurement collecting units, each being provided in a network node, being associated with at least one measurement point at the network node and collecting measurements from the measurement point, the power network being divided into different areas bounded by measurement points from which the measurement collecting units collect measurements, the fault location determining arrangement comprising one or more processors operative to implement a fault location determining function comprising:
obtaining a voltage based on a voltage measurement made at a measurement point, which voltage is obtained based on processing of the voltage measurement made by a measurement collecting unit in the network node associated with the measurement point,
obtaining a number of currents based on current measurements made at a plurality of measurement points, which currents are obtained based on processing of the current measurements made by measurement collecting units in network nodes associated with the measurement points and where the current measurements have been made at the same point in time as the voltage measurement,
comparing each current with a current threshold,
determining a number of phase angles α based on the voltage and all of the currents, each phase angle being a phase angle between the voltage and a different current,
analysing, for each current, whether it crosses the threshold or not and the phase angle to the voltage, and
determining, based on the analysis, if a fault has occurred in the power network and if a fault has occurred also the area in which it has occurred.

The fault location determining function may be implemented by a single processor at a single location in or for the power network, such as via a single fault location determining device. Alternatively, the fault location determining function may be implemented using a number of processors, for instance in one or more of the measurement collecting units, which processors together form the fault location determining arrangement. The measurement collecting units may then also use peer-to-peer communication.

The power network may be a power distribution network. The power distribution network may be a utility distribution network or an industrial distribution network. Additionally, the power distribution network may be a medium voltage, MV, power distribution network. The power network may additionally be an alternating current, AC, power network. The power network may furthermore be a three-phase power network. In this case the voltage measurement may be a three-phase voltage measurement and the current measurements may be three-phase current measurements. The determined voltage may in this case be a zero-sequence voltage and the determined currents may be zero-sequence currents.

Each measurement collecting unit may be provided in a different node. Alternatively, it is possible that at least one node comprises more than one measurement collecting unit.

The measurement collecting unit that obtains the voltage may be connected to the measurement point at which the voltage measurement is made via a corresponding voltage measurement unit. The measurement point at which the voltage measurement is made may thus be connected to a voltage measurement unit, such as a voltage transformer. The measurement collecting units may be connected to current measurement units sensing currents at the measurement points. Thereby measurement points at which current measurements are made may be connected to current measurement units, such as current transformers or Rogowski coils.

The measurement collecting units may be phasor measurement units, PMUs, that collect and time-stamp current and voltage phasors.

As can be seen above, the voltage and the current measurements may have been made at the same point in time. When the measurement collecting units are PMUs, the voltage and the current measurements may have the same time stamps.

The obtaining of the voltage measurement and the current measurements may additionally be synchronized.

A phase angle may represent a direction of the current at the corresponding measurement point. In this case it is additionally possible that an area is found to have a fault if the direction of the current at one or more measurement points at one or more boundaries of the area is above the current threshold and has a direction into the area and no current at the measurement points at the one or more boundaries of the area is above the current threshold with a direction out of the area and that otherwise the area is considered to be healthy.

It is additionally possible that a current that has a direction into an area is a current for which the angle to the voltage lies in a first angle interval and a current that has a direction out from the area is a current for which the angle to the voltage lies outside the first angle interval. The first angle interval may be less than 180 degrees wide. It may for instance be 135 degrees or 90 degrees wide.

It is furthermore possible that the voltage is compared with a voltage threshold and the power network is considered to be healthy if the voltage is below the voltage threshold.

The power network may additionally comprise a number of isolating transformers with neutrals connected to ground according to a grounding scheme, such as a direct grounding or a grounding via Peterson coils. In this case the first angle interval, the current threshold and optionally also the voltage threshold may depend on the grounding scheme used.

For a grounding scheme used in an isolated power network, the first angle interval may be centred around −90 degrees. In this case any current that is above the current threshold and lies outside of the first angle interval has a direction out of the area. In other grounding schemes, the first angle interval may be centred around another angle.

The power network may also comprise a number of current transmission elements in the group of lines, feeders and buses. At least some and with advantage all of the measurement points may be measurement points on current transmission elements. Furthermore, at least two of the measurement points may be measurement points on two different current transmission elements.

The areas may comprise areas of a first type. An area of a first type may be bounded by nodes with measurement collecting units. An area of the first type may additionally comprise at least one current transmission element. The areas may also comprise areas of a second type. A node with a measurement collecting unit may be considered to be an area of the second type.

Generally, all terms used in the claims are to be interpreted according to their ordinary meaning in the technical field, unless explicitly defined otherwise herein. All references to “a/an/the element, apparatus, component, means, step, etc.” are to be interpreted openly as referring to at least one instance of the element, apparatus, component, means, step, etc., unless explicitly stated otherwise. The steps of any method disclosed herein do not have to be performed in the exact order disclosed, unless explicitly stated.

### BRIEF DESCRIPTION OF THE DRAWINGS

Aspects and embodiments are now described, by way of example, with reference to the accompanying drawings, in which:

FIG. 1 is a diagram schematically illustrating a first type of power network with a first number of measurement collecting units used to divide the network into areas;

FIG. 2 is a diagram schematically illustrating the first type of power network with a second number of measurement collecting units used to divide the network into areas;

FIG. 3 is a diagram schematically illustrating a second type of power network with a third number of measurement collecting units used to divide the network into areas;

FIG. 4 schematically shows a realization of a fault location determining device used in the power networks;

FIG. 5 schematically shows a computer readable storage medium with computer program code used to implement a fault location determining function of the fault location determining device;

FIG. 6 shows a flow chart of a number of steps in a method of determining a fault location;

FIG. 7 shows a current threshold, an angle and a first angle interval between current and voltage used to determine if a fault occurs in an area for a first grounding scheme, and

FIG. 8 is a diagram schematically illustrating the second type of power network when a fault has occurred in a ninth area, and

FIG. 9 schematically shows a current measurement unit and a voltage measurement unit connected between a first measurement collecting unit and a first measurement point of a first current transmission element of the first type of network.

### DETAILED DESCRIPTION

The aspects of the present disclosure will now be described more fully hereinafter with reference to the accompanying drawings, in which certain embodiments of the invention are shown.

These aspects may, however, be embodied in many different forms and should not be construed as limiting rather, these embodiments are provided by way of example so that this disclosure will be thorough and complete, and to fully convey the scope of all aspects of invention to those skilled in the art. Like numbers refer to like elements throughout the description.

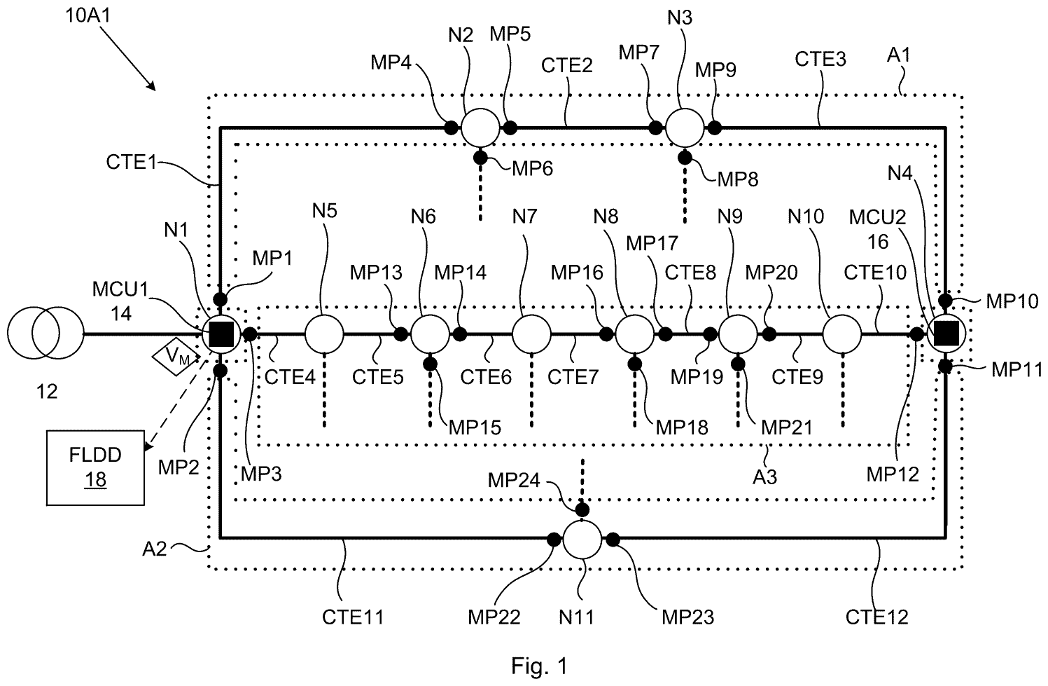

FIG. 1 shows a first type of power network 10A1 comprising a first number of measurement collecting units. In this case the number of measurement collecting units is two. In this example the power network is a meshed power distribution network. The power distribution network may be a utility distribution network or an industrial distribution network. The power network may also be a medium voltage, MV, power network. Furthermore, the power network is also an alternating current, AC, power network, which may additionally be a three-phase power network. The power network may additionally comprise isolated or compensated neutral grounding, for instance using isolating transformers with neutrals connected to ground, either directly or via Petersen coils.

As an example, the network 10A1 comprises a transformer 12. The transformer 12 may have a primary side connected to a power transmission network (not shown). The transformer 12 also has a secondary side connected to a first node N1, which first node N1 is in turn connected to a first end of a first current transmission element CTE1. A second node N2 is in turn connected to a second end Of the first current transmission element CTE1 as well as to a first end of a second current transmission element CTE2. A third node N3 is connected to a second end of the second current transmission element CTE2 as well as to a first end of a third current transmission element CTE3. A fourth node N4 is in turn connected to a second end of the third current transmission element CTE3. Thereby a first branch is formed between the first and the fourth nodes N1 and N4.

The first node N1 is also connected to first end of a fourth current transmission element CTE4, while a fifth node N5 is connected to a second end of the fourth current transmission element CTE4 as well as to a first end of a fifth current transmission element CTE5. A sixth node N6 is connected to a second end of the fifth current transmission element CTE5 as well as to a first end of a sixth current transmission element CTE6. A seventh node N7 is connected to a second end of the sixth current transmission element CTE6 as well as to a first end of a seventh current transmission element CTE7. An eighth node N8 is connected to a second end of the seventh current transmission element CTE7 as well as to a first end of an eighth current transmission element CTE8. A ninth node N9 is connected to a second end of the eighth current transmission element CTE8 as well as to a first end of a ninth current transmission element CTE9. A tenth node N10 is connected to a second end of the ninth current transmission element CTE9 as well as to a first end of a tenth current transmission element CTE10. The fourth node N4 is in turn connected to a second end of the tenth current transmission element CTE10. Thereby a second branch is formed between the first and the fourth nodes N1 and N4.

The first node N1 is also connected to a first end of an eleventh current transmission element CTE11. An eleventh node N11 is connected to a second end Of the eleventh current transmission element CTE11 as well as to a first end of a twelfth current transmission element CTE12. The fourth node N4 is in this case also connected to a second end of the twelfth current transmission element CTE12. Thereby a third branch is formed between the first and the fourth nodes N1 and N4.

The current transmission elements may be of a variety of types. They may be busbars, feeders or power lines, such as overhead or underground power lines.

The nodes may provide isolation of the current transmission elements from each other and may therefore comprise isolating transformers, which may be three-phase transformers with neutrals connected to ground according to a grounding scheme, which grounding scheme may be a direct connection to ground or a connection to ground via a Petersen coil. The second, third, fifth, sixth, seventh, eighth, ninth, tenth and eleventh nodes N2, N3, N5, N6, N7, N8, N9, N10 and N11 are also connected to exemplifying overhead sections that may each continue for a number of further nodes. This is indicated with dashed lines. The power network may thus comprise a number of isolating transformers with neutrals connected to ground according to a grounding scheme, such as a direct grounding or a grounding via Peterson coils.

Furthermore, there are a number of measurement points in the power network 10A1. At least some and with advantage all of the measurement points may be measurement points on current transmission elements. Furthermore, at least two of the measurement points may be measurement points on two different current transmission elements. Thus the measurement points are provided at the different current transmission elements.

There is a first measurement point MP1 at the first end of the first current transmission element CTE1, a second measurement point MP2 at the first end of the eleventh current transmission element CTE11, a third measurement point MP3 at the first end of the fourth current transmission element CTE4, a fourth measurement point MP4 at the second end of the first current transmission element CTE1, a fifth measurement point MP5 at the first end of the second current transmission element CTE2, a sixth measurement point MP6 at a connection to an overhead section of the second node N2, a seventh measurement point MP7 at the second end of the second current transmission element CTE2, an eighth measurement point MP8 at a connection to an overhead section of the third node N3, a ninth measurement point MP9 at the first end of the third current transmission element CTE3, a tenth measurement point MP10 at the second end of the third current transmission element CTE3, an eleventh measurement point MP11 at the second end of the twelfth current transmission element CTE12, a twelfth measurement point MP12 at the second end of the tenth current transmission element CTE10, a thirteenth measurement point MP13 at the second end of the fifth current transmission element CTE5, a fourteenth measurement point MP14 at the first end of the sixth current transmission element CTE6, a fifteenth measurement point MP15 at a connection to an overhead section of the sixth node N6, a sixteenth measurement point MP16 at the second end of the seventh current transmission element CTE7, a seventeenth measurement point MP17 at the first end of the eighth current transmission element CTE8, an eighteenth measurement point MP18 at a connection to an overhead section of the eighth node N8, a nineteenth measurement point MP19 at the second end of the eighth current transmission element CTE8, a twentieth measurement point MP20 at the first end of the ninth current transmission element CTE9, a twenty-first measurement point MP21 at a connection to an overhead section of the ninth node N9, a twenty-second measurement point MP22 at the second end of the eleventh current transmission element CTE11, a twenty-third measurement point MP23 at the first end of the twelfth current transmission element CTE12 and a twenty-fourth measurement point MP24 at a connection to an overhead section of the eleventh node N11.

Current measurement units, such as current transformers or Rogowski coils, may be provided in the nodes at the various measurement points. There is also at least one voltage measurement unit in the power network, such as a voltage transformer. A voltage measurement unit may for instance be provided in the first node N1 for measuring the voltage at any of the first, second or third measurement points MP1, MP2, MP3. Thereby, the measurement point at which the voltage measurement is made is connected to a voltage measurement unit and the measurements points at which current measurements are made are connected to current measurement units.

The power network 10A1 also comprises a first number of measurement collecting units. The measurement collecting units may be placed in nodes of the network. Each measurement collecting unit may be provided in a different node. Alternatively, it is possible that at least one node comprises more than one measurement collecting unit. In the present example the number of measurement collecting units are two and these are placed in the first and the fourth nodes N1, N4. There is thus a first measurement collecting unit MCU1 14 in the first node N1 and a second measurement collecting unit MCU2 16 in the fourth node N4. The measurement collecting units 14, 16 may be phasor measurement units (PMUs) that collect and time-stamp current and voltage phasors. The PMUs may be syncrophasor units that collect current and voltage measurements made by current and voltage measurement units at measurement points at the nodes in which they are provided. The measurement collecting units thus collect measurements from associated measurement points. The first measurement collecting unit 14 collects current measurements made at the first, second and third measurement points MP1, M2, MP3 and the second measurement collecting unit 16 collects current measurements made at the tenth, eleventh and twelfth measurement points MP10, MP11, MP12. Additionally, the first measurement collecting unit 14 collects a voltage measurement VM, which voltage measurement could have been made at any of the first, second and third measurement points MP1, MP2, MP3. The measurement point at which the voltage measurement VM is made can be seen as a dedicated voltage measurement point. The measurement collecting units 14, 16 provide the collected measurements to a fault location determining device FLDD 18. In FIG. 1 only the first measurement collecting unit 14 is shown as sending measurements to the fault location determining device 18. However, it should be realized that also the second measurement collecting unit 16 sends measurements to the fault location determining device 18.

Furthermore, the measurement collecting units are also used to divide the power network into different areas. More specifically, the power network is divided into different areas that are bounded by measurement points from which the measurement collecting units collect measurements. The first branch between the first and the fourth nodes N1, N4, i.e. the first, second and third current transmission elements CTE1, CTE2, CTE3 and the second and third nodes N2, N3 form a first area A1 of a first type, which first area A1 is bounded by the first and tenth measurement points MP1, MP10 from which the first and second current measurement units 14, 16 in the first and fourth nodes N1, N4 collect measurements. The second branch with the fourth, fifth, sixth, seventh, eighth, ninth and tenth current transmission elements CTE4, CTE5, CTE6, CTE7, CTE8, CTE9, CTE10 together with the fifth, sixth, seventh, eighth, ninth and tenth nodes N5, N6, N7, N8, N9, N10 form a second area A2 of the first type, which second area A2 thus is bounded by the third and twelfth measurement points MP3, MP12 from which the first and second measurement collecting units 14, 16 collect measurements. In a similar manner the third branch between the first and the fourth nodes N1, N4, i.e. the eleventh and twelfth current transmission elements CTE11, CTE12 and the eleventh node N11 form a third area A3 of the first type, which third area A3 thus is bounded by the second and eleventh measurement points MP2, MP11 from which the first and second measurement collecting units 14, 16 collect measurements. It should here be realized that it is possible to place the two measurement collecting units 14, 16 in other nodes of the power network. Also, the nodes in which the measurement collecting units are placed can be considered to be areas of the network. These areas are areas of a second type. The areas are shown with dotted lines.

Thereby it can be seen that the power network 10A1 comprises a number of measurement points, a number of network nodes and a number of measurement collecting units, each being provided in a network node and being associated with at least one measurement point at the network node. Furthermore, the power network is divided into different areas A1, A2, A3 bounded by measurement points MP1, MP10, MP3, MP12, MP2, MP11 from which the measurement collecting units 12, 14 collect measurements, where the areas comprise areas of a first type comprising at least one current transmission element, where each area of the first type is bounded by at least one node comprising a measurement collecting unit. Each node with a measurement collecting unit can additionally provide an area of a second type.

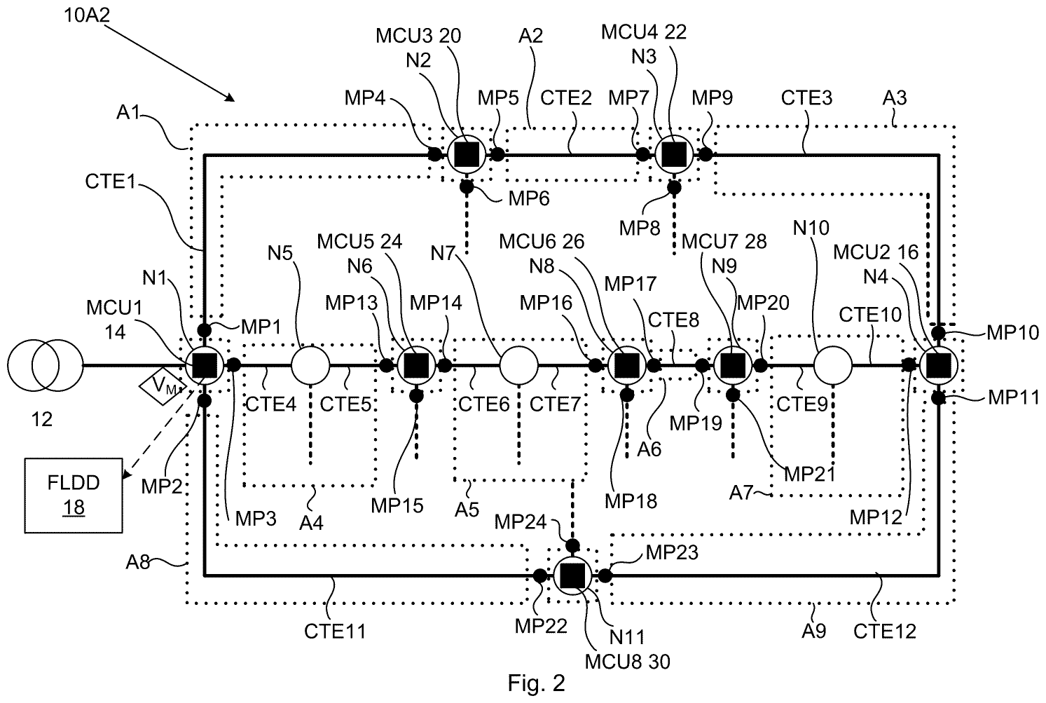

FIG. 2 shows the first type of power network 10A2 comprising a second number of measurement collecting units, which second number as an example is eight. Also here each measurement collecting unit may be provided in a different node. Alternatively, it is possible that at least one node comprises more than one measurement collecting unit. In addition to the first and second measurement collecting unit 14, 16 in the first and fourth nodes N1, N4, there is in this example six further measurement collecting units. More particularly, there is a third measurement collecting unit MCU3 20 located in the second node N2, a fourth measurement collecting unit MCU4 22 located in the third node N3, a fifth measurement collecting unit MCU5 24 located in the sixth node N6, a sixth measurement collecting unit MCU6 26 located in the eighth node N8, a seventh measurement collecting unit MCU7 28 located in the ninth node N9 and an eighth measurement collecting unit MCU8 30 located in the eleventh node N11.

Also here, the first measurement collecting unit 14 collects a voltage measurement VM made at one of the first, second and third measurement points MP1, M2, MP3 and current measurements made at the first, second and third measurement points MP1, M2, MP3, while the second measurement collecting unit 16 collects current measurements made at the tenth, eleventh and twelfth measurement points MP10, MP11, MP12. Additionally, the third measurement collecting unit 20 collects current measurements made at the fourth, fifth and sixth measurement points MP4, MP5, MP6, the fourth measurement collecting unit 22 collects current measurements made at the seventh, eighth and ninth measurement points MP7, MP8, MP9, the fifth measurement collecting unit 24 collects current measurements made at the thirteenth, fourteenth, and fifteenth measurement points MP13, MP14, MP15, the sixth measurement collecting unit 26 collects current measurements made at the sixteenth, seventeenth and eighteenth measurement points MP16, MP17, MP18, the seventh measurement collecting unit 28 collects current measurements made at the nineteenth, twentieth and twenty-first measurement points MP19, MP20, MP21 and the eighth measurement collecting unit 30 collects current measurements made at the twenty-second, twenty-third and twenty-fourth measurement points MP22, MP23, MP24. Although only the first measurement collecting unit 14 is shown as sending measurements to the fault location determining device 18, it should be realized that also here all the other measurement collecting units do it too.

The first current transmission element CTE1 forms a first area A1 of the first type, which first area A1 is bounded by the first and fourth measurement points MP1, MP4, from which the first and third measurement collecting units 14, 20 in the first and second nodes N1, N2 collect measurements. The second current transmission element CTE2 forms a second area A2 of the first type, which second area A2 is bounded by the fifth and seventh measurement points from which the third and fourth measurement collecting units 20, 22 in the second and third nodes N2, N3 collect measurements. The third current transmission element CTE3 forms a third area A3 of the first type, which third area A3 is bounded by the ninth and tenth measurement points MP9, MP10 from which the fourth and second measurement collecting units 22, 16 in the third and fourth nodes N3, N4 collect measurements. The fourth and fifth current transmission elements CTE4, CTE5 together with the fifth node N5 form a fourth area A4 of the first type, which fourth area A4 is bounded by the third and thirteenth measurement points MP3, MP13 from which the first and fifth measurement collecting units 14, 24 in the first and sixth nodes N1, N6 collect measurements. The sixth and seventh current transmission elements CTE6, CTE7 together with the seventh node N7 form a fifth area A5 of the first type, which fifth area A5 is bounded by the fourteenth and sixteenth measurement points MP14, MP16 from which the fifth and sixth measurement collecting units 24, 26 in the sixth and eighth nodes N6, N8 collect measurements. The eighth current transmission element CTE8 forms a sixth area A6 of the first type, which sixth area A6 is bounded by the seventeenth and nineteenth measurement points MP17, MP19 from the sixth and seventh measurement collecting units 26, 28 in the eighth and ninth nodes N8, N9 collect measurements. The ninth and tenth current transmission element CTE9, CTE10 together with the tenth node N10 form a seventh area A7 of the first type, which seventh area A7 is bounded by the twentieth and twelfth measurement points MP20, MP12 at which the seventh and second measurement collecting units 28, 16 in the ninth and fourth nodes N9, N4 collect measurements. The eleventh current transmission element CTE11 forms an eighth area A8 of the first type, which eighth area A8 is bounded by the second and twenty-second measurement points MP2, MP22 at which the first and eighth measurement collecting units 14, 30 in the first and eleventh nodes N1, N11 collect measurements. Finally, the twelfth current transmission element CTE12 forms a ninth area A9 of the first type, which ninth area A9 is bounded by the twenty-third and eleventh measurement points MP23, MP11 at which the eighth and second measurement collecting units 30, 16 of the eleventh and fourth nodes N11, N4 collect measurements. Also the nodes in which the measurement collecting units are placed can be considered to be areas of the second type. Thus, the first, second, third, fourth, sixth, eighth, ninth and eleventh nodes N1, N2, N3, N4, N6, N8, N9, N11 are also separate areas of the second type. The areas are indicated through dotted lines.

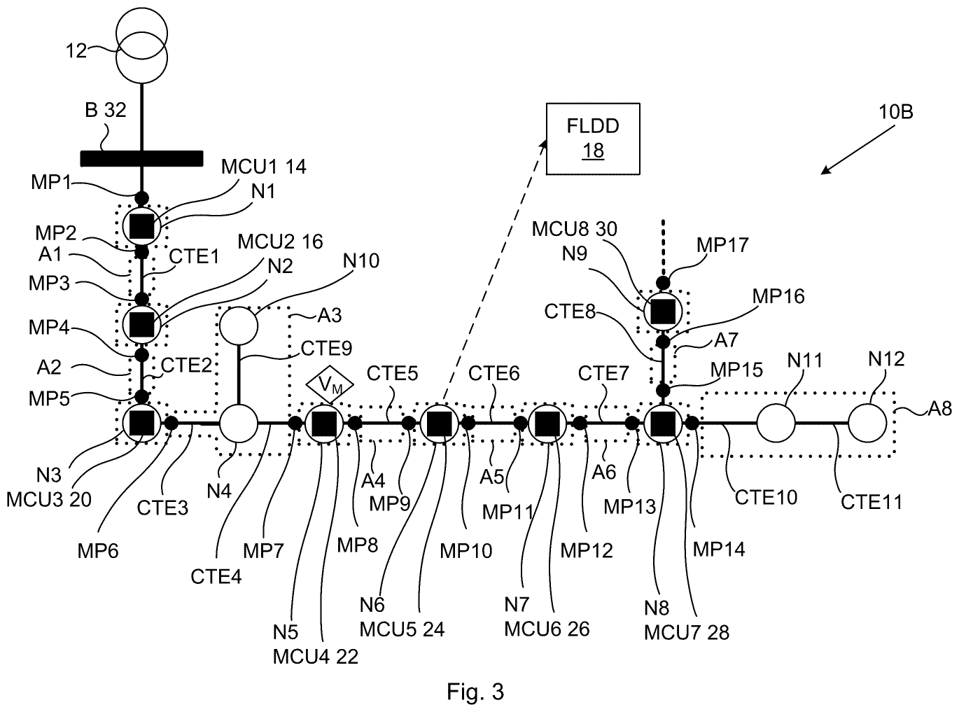

FIG. 3 shows a second type of power network 10B, which is a radial distribution network. Also this power distribution network may be a utility distribution network or an industrial distribution network. It may also be a medium voltage, MV, power distribution network.

As an example the network 10B comprises a transformer 12 connected to a busbar B 32, which may be part of a Primary Substation. Furthermore, a feeder is connected to the busbar 32. The feeder has a first node N1 connected between the busbar 32 and a first end of a first current transmission element CTE1. A second node N2 is in turn connected between a second end of the first current transmission element CTE1 and a first end of a second current transmission element CTE2. A third node N3 is connected between a second end of the second current transmission element CTE2 and a first end of a third current transmission element CTE3. A fourth node N4 is connected between a second end of the third current transmission element CTE3, a first end of a fourth current transmission element CTE4 and a first end of ninth current transmission element CTE9. A fifth node N5 is connected between a second end of the fourth current transmission element CTE4 and a first end of a fifth current transmission element CTE5. A sixth node N6 is connected between a second end of the fifth current transmission element CTE5 and a first end of a sixth current transmission element CTE6. A seventh node N7 is connected between a second end of the sixth current transmission element CTE6 and a first end of a seventh current transmission element CTE7. An eight node N8 is connected between a second end of the seventh current transmission element CTE7, a first end of an eight current transmission element CTE8 and a first end of a tenth current transmission element CTE10. A ninth node N6 is connected between a second end of the eight current transmission element CTE8 and a remainder of the feeder leading to a number of further nodes. Furthermore, there is also a tenth node N10 connected to a second end of the ninth current transmission element CTE9, an eleventh node N11 connected between a second end of the tenth current transmission element CTE10 and a first end of an eleventh current transmission element CTE11 as well as a twelfth node N12 connected to a second end of the eleventh current transmission element CTE 11.

The current transmission elements may be of a variety of types. They may be busbars, feeders or power lines, such as overhead or underground power lines.

Furthermore, there are a number of measurement points in the power network 10B, which measurement points are provided at the different current transmission elements as well as at the remainder of the feeder connected to the ninth node N9.

There is a first measurement point MP1 at the junction between the first node N1 and the busbar 32, a second measurement point MP2 at the first end of the first current transmission element CTE1, a third measurement point MP3 at the second end of the first current transmission element CTE1, a fourth measurement point MP4 at the first end of the second current transmission element CTE2, a fifth measurement point MP5 at the second end of the second current transmission element CTE2, a sixth measurement point MP6 at the first end of the third current transmission element CTE3, a seventh measurement point MP7 at the second end of the fourth current transmission element CTE4, an eighth measurement point MP8 at the first end of the fifth current transmission element CTE5, a ninth measurement point MP9 at the second end of the fifth current transmission element CTE5, a tenth measurement point MP10 at the first end of the sixth current transmission element CTE6, an eleventh measurement point MP11 at the second end of the sixth current transmission element CTE6, a twelfth measurement point MP12 at the first end of the seventh current transmission element CTE7, a thirteenth measurement point MP13 at the second end of the seventh current transmission element CTE7, a fourteenth measurement point MP14 at the first end of the tenth current transmission element CTE10, a fifteenth measurement point MP15 at the first end of the eighth current transmission element CTE8, a sixteenth measurement point MP16 at the second end of the eighth current transmission element CTE8 and a seventeenth measurement point MP17 at the rest of the feeder at the ninth node N9.

Current measurement units, such as current transformers or Rogowski coils, may be provided at the various measurement points. There is also at least one voltage measurement unit in the power network, such as a voltage transformer. A voltage measurement unit may for instance be provided at the fifth node N5 for measuring the voltage at any of the seventh or eighth measurement points MP7, MP8. The measurement point at the fifth node N5 that is used for voltage measurement may be a dedicated voltage measurement node.

In this power network 10B there is third number of measurement collecting units, which third number as an example is also eight. Each measurement collecting unit may be provided in a different node. Alternatively, it is possible that at least one node comprises more than one measurement collecting unit. In the present example, there is a first measurement collecting unit MCU1 14 in the first node N1, a second measurement collecting unit MCU2 16 in the second node N2, a third measurement collecting unit MCU3 20 in the third node N3, a fourth measurement collecting unit MCU4 22 in the fifth node N5, a fifth measurement collecting unit MCU5 24 in the sixth node N6, a sixth measurement collecting unit MCU6 26 in the seventh node N7, a seventh measurement collecting unit MCU7 28 in the eighth node N8 and an eighth measurement collecting unit MCU8 30 in the ninth node N9. Also there nodes may comprise isolating transformers that employ one of the grounding schemes.

Also here the measurement points from which measurement collecting units collect measurements are used to divide the power network into different areas. The first current transmission element CTE1 forms a first area A1 of the first type, which first area A1 is bounded by the second and third measurement points MP2, MP3 from which the first and second measurement collecting units 14, 16 in the first and second nodes N1, N2 collect measurements. The second current transmission element CTE2 forms a second area A2 of the first type, which second area A2 is bounded by the fourth and fifth measurement points MP4, MP5 from which the second and third measurement collecting units 16, 20 in the second and third nodes N2. N3 collect measurements. The third, fourth and ninth current transmission elements CTE3, CTE4, CTE9 and the fourth node N4 form a third area A3 of the first type, which third area A3 is bounded by the sixth and seventh measurement points MP6, MP7 from which the third and fourth measurement collecting units 20, 22 in the third and fifth nodes N3, N5 collect measurements. The fifth current transmission element CTE5 forms a fourth area A4 of the first type, which fourth area A4 is bounded by the eighth and ninth measurement points MP8, MP9 from which the fourth and fifth measurement collecting units 22, 24 in the fifth and sixth nodes N5, N6 collect measurements. The sixth current transmission element CTE6 forms a fifth area A5 of the first type, which fifth area A5 is bounded by the tenth and eleventh measurement points MP10, MP11 from which the fifth and sixth measurement collecting units 24, 26 in the sixth and seventh nodes N6, N7 collect measurements. The seventh current transmission element CTE7 forms a sixth area A6 of the first type, which sixth area A6 is bounded by the twelfth and thirteenth measurement points MP12, MP13 from which the sixth and seventh measurement collecting units 26, 28 in the seventh and eighth nodes N7, N8 collect measurements. The eighth current transmission element CTE8 forms a seventh area A7 of the first type, which seventh area A7 is bounded by the fifteenth and sixteenth measurement points MP15, MP16 from which the seventh and eighth measurement collecting units 28, 30 in the eighth and ninth nodes N8, N9 collect measurements. Finally, the tenth and eleventh current transmission elements CTE10, CTE11 together with the eleventh and twelfth nodes N11, N12 form an eight area A8 of the first type, which eighth area A8 is bounded by the fourteenth measurement point MP14 from which the seventh measurement collecting unit 28 in the eighth node N8 collects measurements. Also the nodes in which the measurement collecting units are placed can be considered to be areas of the second type. Thus, the first, second, third, fifth, sixth, seventh, eighth and ninth nodes N1, N2, N3, N5, N6, N7, N8, N9 may be considered as areas of the second type in power network.

The first measurement collecting unit 14 collects current measurements made at the first and second measurement points MP1, MP2, the second measurement collecting unit 16 collects current measurements made at the third and fourth measurement points MP3, MP4 and the third measurement collecting unit 20 collects current measurements made at the fifth and sixth measurement points MP5, MP6. The fourth measurement collecting unit 22 collects current measurements made at the seventh and eighth measurement points MP7, MP8. Additionally, it collects a voltage measurement made at one of the seventh and eighth measurement points MP7, MP8. The fifth measurement collecting unit 24 collects current measurements made at the ninth and tenth measurement points MP9, MP10, the sixth measurement collecting unit 26 collects current measurements made at the eleventh and twelfth measurement points MP11, MP12, the seventh measurement collecting unit 28 collects current measurements made at the thirteenth, fourteenth and fifteenth measurement points MP13, MP14, MP15 and the eighth measurement collecting unit 30 collects current measurements made at the sixteenth and seventeenth measurement points MP16, MP17. In FIG. 3 only the fifth measurement collecting unit 24 is shown as sending measurements to the fault location determining device 18. It should be realized that also here the other measurement collecting units send measurements to the fault location determining device 18.

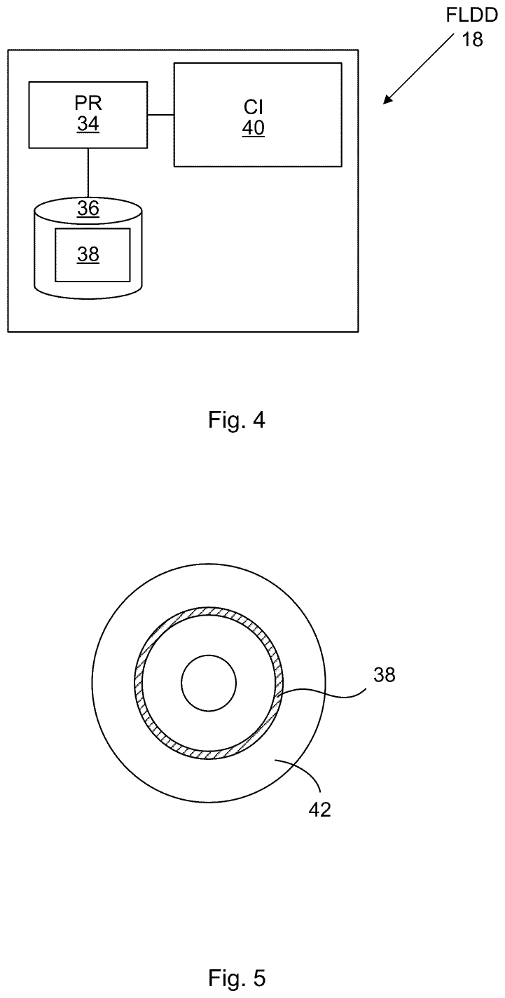

FIG. 4 schematically shows one realization of the fault location determining device FLDD 18.

The fault location determining device 18 comprises a processor PR 34 and a data storage 36 with computer program instructions or computer program code 38 that, when executed by the processor 34, implements a fault location determining function. There is also a communication interface Cl 40. The communication interface 40 may be a wireless interface, an Ethernet interface or even an optical interface for communicating with the measurement collecting units.

The fault location determining device 18 may thus comprise a processor 34 with associated program memory 36 including computer program code 38 for implementing the fault location determining function.

A computer program may also be provided via a computer program product, for instance in the form of one or more computer-readable storage media or data carriers, like CD ROMs or a memory sticks, carrying such a computer program with the computer program code, which will implement the fault location determining function when being loaded into one or more processors. One such computer-readable storage medium in the form of a CD ROM 42 with the above-mentioned computer program code 38 is schematically shown in FIG. 5.

According to aspects of the present disclosure, there is a fault location determining arrangement comprising one or more processors and which fault location determining arrangement performs the fault location determination function with respect to the power network in or for which it is provided. In the examples of FIGS. 1, 2, and 3, the fault location determining arrangement is provided as the fault location determining device 18 comprising a processor performing the fault location determining function. In this example, the fault location determining function may thus be implemented by a single processor of a single fault location determining device at a single location in or for the power network. The fault location determining device may be placed in a central location as indicated in FIG. 3 or in one of the nodes, for instance as a part of a measurement collecting unit.

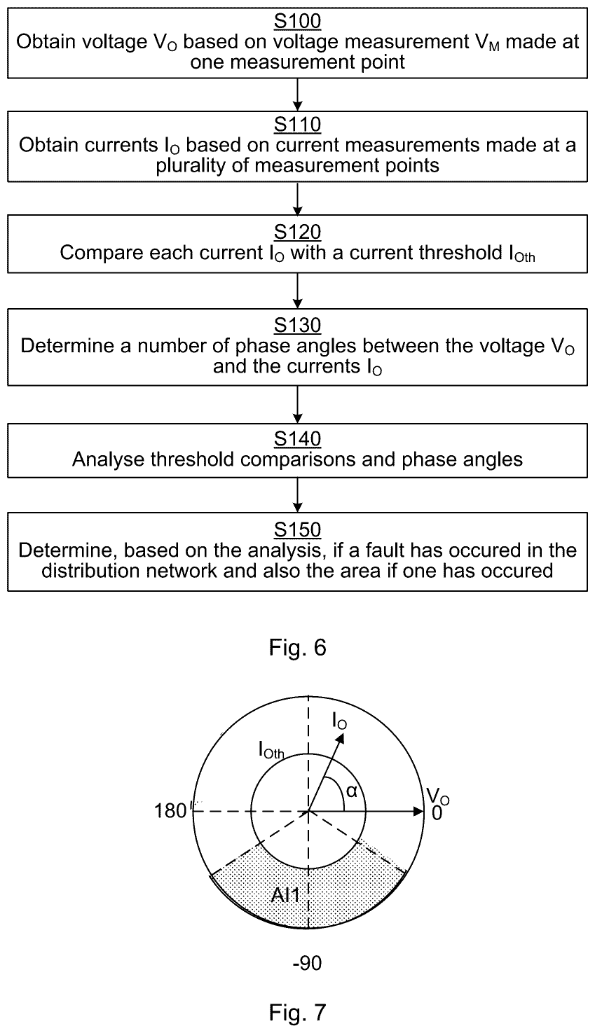

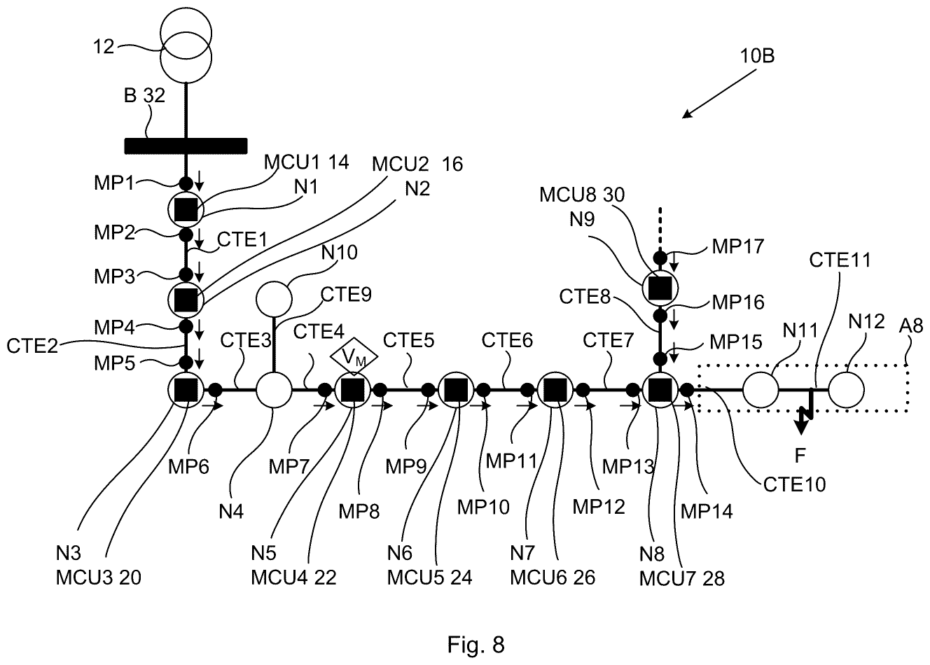

The fault location determining function determines the location of a fault in the power network. How this can be done for the radial power distribution network in FIG. 3, will now be further elaborated with reference also being made to FIGS. 6, 7 and 8, where FIG. 6 shows a flow chart of a number of steps in a method of determining a fault location, FIG. 7 shows a relationship between current and voltage used to determine if a fault occurs in an area for a first grounding scheme and FIG. 8 is a diagram schematically illustrating the second type of power network 10B when a fault has occurred in the eighth area A8 of this network 10B.

One voltage measurement unit may measure a voltage at a corresponding measurement point of a network node and supply the voltage measurement to a corresponding measurement collecting unit associated with the network node. As an example, a voltage measurement unit makes a voltage measurement VM at the seventh measurement point MP7 and supplies the measurement to the fourth measurement collecting unit 22 of the fifth node N5. The voltage measurement may additionally be a three-phase voltage measurement obtained at the measurement point. The fourth measurement collecting unit 22 may in turn process the voltage measurement VM, which may involve forming at least one voltage phasor based on the voltage measurement. It may also involve time stamping the voltage phasor. The processed voltage measurement is then provided to the fault location determining function in the fault location determining arrangement.

A plurality of current measurement units may also each measure a current at a corresponding plurality of measurement points and supply the current measurements to corresponding measurement collecting units in network nodes associated with the measurement points. As an example, current measurement units at all of the measurement points MP1-MP17 make current measurements and supply these to the corresponding measurement collecting units 14, 16, 20, 22, 24, 26, 28, 30 and where the current measurements are made at the same time as the voltage measurement V. Also the current measurements may be three-phase current measurements obtained at the measurement points. The measurement collecting units 14, 16, 20, 22, 24, 26, 28, 30 may process the current measurements, which may involve forming current phasors based on the current measurements. The processing may also involve time stamping the current phasors. The processed current measurements are then provided to the fault location determining function in the fault location determining arrangement. The processed current measurements may comprise processed current measurements sent from the fourth measurement collecting unit 22 used for the voltage. However, the processed current measurements also comprise processed current measurements sent from all of the other measurement collecting units. Thereby the fault location determining device 18 receives processed current measurements from the fourth measurement collecting unit 22 that have been measured at the seventh and eighth measurement points MP7, MP8 as well as processed current measurements that have been collected by the other measurement collecting units 14, 16, 20, 24, 26, 28, 30 from the other measurement points MP1, MP2, MP3, MP4, MP5, MP6, MP9, MP10, MP11, MP12, MP13, MP14, MP15, MP16, MP17. The processed current measurements are thus received from all of the measurement points to which all of the measurement collecting units are connected.

The voltage measurement and the current measurements may be synchronized. The fault location determining device 18 may thus receive the processed voltage and current measurements that have the same time stamp simultaneously from all the measurement collecting units. For this reason, it is also possible that the time-synchronization has an accuracy, which may be an accuracy of below 0.1 microseconds.

The fault location determining function may start with the fault location determining device 18 obtaining a voltage V_{O} based on the voltage measurement V_{M} made at the previously mentioned measurement point MP8, S100. This voltage V_{O} is based on processing of the voltage measurement V_{M} made by the used measurement collecting unit 22, which processing may at least comprise time stamping. The voltage V_{O} may be a phase voltage, for instance in the form of a phasor supplied by the used measurement collecting unit 22. As an alternative the fault location determining function may perform additional processing such as combining the different phase voltages in order to obtain the voltage V_{O} as a zero-sequence voltage.

The fault location determining function also obtains a number of currents I_{O} based on current measurements made at the plurality of measurement points MP1-MP17, S110, which currents I_{O} are also obtained based on processing of the current measurements made by measurement collecting units 14, 16, 20, 22, 24, 26, 28, 30, which processing may at least comprise time stamping. The currents I_{O} that are obtained may be phase currents supplied by the measurement collecting units, for instance in the form of phasors. As an alternative the fault location determining function may perform additional processing such as combining the different phase currents in order to obtain the currents I_{O} as zero-sequence currents.

Thereafter the fault location determining device 18 continues and investigates if there is a fault and if one such fault is determined then also the area in which the fault has occurred. This involves an investigation of the obtained voltage and currents, which as an example are zero-sequence currents and voltages.

The investigation may also optionally involve comparing the obtained voltage V_{O} with a voltage threshold and declaring or considering the power network to be healthy in case the voltage is below the voltage threshold.

In case the voltage V_{O} is above the voltage threshold, the investigation continues with comparing each current I_{O} with a current threshold I_{Oth}, S120. There is also a determining of a number of phase angles based on the obtained voltage V_{O} and all of the obtained currents I_{O}, S130, where each phase angle is a phase angle between the obtained voltage V_{O} and a different obtained current I_{O}. The determining of a number of phase angles may thus be a determining of a number of phase angles between the obtained voltage V_{O} and the obtained currents I_{O}. There is thus determined one phase angle for each current being received by the fault location determining device 18. Each current I_{O} is also compared with the current threshold lath, which current threshold may be set to a level that indicates the existence of a fault.

The investigation may additionally comprise analysing the threshold comparisons and phase angles, S140, and a determination, based on the analysis, of if a fault has occurred in the power network and if such a fault is deemed to have occurred, the area in which it has occurred, S150. There is thus an analysing, for each obtained current I_{O}, whether it crosses the threshold I_{Oth} or not and an analysing of the phase angle to the obtained voltage V_{O} as well as a determining, based on the analysis, if a fault has occurred in the power network and if a fault has occurred also the area in which it has occurred.

One way in which the analysis can be made for a first grounding scheme for an isolated power network can be explained with reference being made to FIG. 7. The obtained voltage V_{O} is a vector with which an obtained current vector I_{O} is compared, which current vector represents the current of a measurement point, where the voltage and current measurements have been made at the same time. It can be seen that the obtained current I_{O} is compared with a current threshold lath, shown as a small circle in FIG. 7 and if the obtained current I_{O} is above the threshold lath, the angle α between the current I_{O} and voltage V_{O} is analysed. The current I_{O} is more particularly analysed with regard to a first angle interval All, where the first angle interval All according to the first grounding scheme is as an interval centred around −90. The first angle interval A1 may be less than 180 degrees wide. It may for instance be 135 degrees, 90 degrees or 60 degrees wide. An angle in the first angle interval All indicates that the current I_{O} is a current with a direction into an area, while an angle that is outside of the first angle interval All indicates that the current is a current with a direction out of the area. This type of analysis is then made for the currents at all of the measurement points. An area is then found to include a fault in case a current at a boundary of the area is above the threshold and has an angle to the voltage in the first angle interval All, while none of the currents at other boundaries to the same area are above the threshold and have an angle to the voltage outside of the first angle interval All. If these conditions are not fulfilled, then the area is considered healthy.

The operation can then also be explained in the following way. The area below the current threshold I_{Oth} (for all the angles) is a first region R1, the first angle interval All above the current threshold I_{Oth} is a third region R3 and the area that surrounds the first angle interval above the current threshold lot is a second region R2. For this definition an area of the power network can be considered faulty and healthy for the following combinations:

| Area | |
|---|---|
| Status | Position of I_{O} with respect to V_{O} |
| Faulted | At least one boundary current I_{O} falls in “R3” and the remaining |
| | boundary currents I_{O} that do not fall in “R3”, if any, fall in “R1” |
| | (never in “R2”) |
| Healthy | At least one boundary current I_{O} falls in “R2” and the remaining |
| | boundary currents I_{O} that do not fall in “R2”, if any, fall in “R1” |
| | or “R3” |
| | All boundary currents I_{O} fall in “R1” |

The phase angle α thus represents a direction of the current at the corresponding measurement point and an area is found to have a fault if the direction of the current at one or more measurement points at one or more boundaries of the area is above the current threshold and has a direction into the area and no current at the measurement points at the one or more boundaries of the area is above the current threshold with a direction out of the area. If this condition is not fulfilled the investigated area is considered to be healthy. Furthermore, as can be seen above a current that has a direction into an area is a current for which the angle to the voltage lies in the first angle interval, which as an example may be an interval around the angle −90 degrees, and a current that has a direction out from the area is a current for which the angle to the voltage is outside of the first angle interval.

The same type of investigations can be carried out for the nodes with the measurement collecting units, i.e. for the areas of the second type.

How this can be interpreted is exemplified in FIG. 8, where a fault F has occurred in the eleventh current transmission element CTE11 in the eight area A8. In the drawing also the directions of the currents at the different measurement points are shown. It can here be seen that a current above the threshold is found to enter the eighth area A8. However, there is no current above the threshold leaving this eighth area A8 and consequently it is deemed to be faulty. It can at the same time be seen that for the first-seventh areas A1-A7, a current above the threshold that enters the area at one boundary is complemented by a current at another boundary that leaves the area. Thus, none of the first-seventh areas A1-A7 are deemed faulty. Neither are any of the first, second, third, fifth, sixth, seventh, eighth or ninth nodes N1, N2, N3, N5, N6, N7, N8, N9 with the measurement collecting units 14, 16, 20, 22, 24, 26, 28, 30.

After a fault has been located in an area, the area may then be disconnected for protective measures. In the example of FIG. 8, it is for instance possible that the first end of the tenth current transmission element CTE10 is connected to the eighth node N8 via a circuit breaker. It is possible that this circuit breaker is opened in case of a fault.

One voltage of the power network can thus be used for all investigations. It can thus be seen that the voltage needs not be a voltage measured from the same current transmission element as the current used in the investigation. It can thereby be seen that an area can be located using only one voltage measurement unit, which reduces the cost and simplifies the complexity of the network. It is not uncommon with power networks having more than 200 measurement points. The savings may therefore be considerable.

It can here also be mentioned that the first angle interval, the current threshold and the voltage threshold if present may depend on the grounding scheme used. For instance, the first angle interval may be centred around another angle than −90 degrees in other grounding schemes.

The operation is essentially the same for the first and second variations of the first type of power network 10A1, 10A2. However, in this case only the first measurement collecting unit 14 obtains a voltage measurement that is made at one of the first, second and third measurement points MP1, MP2, MP3, which voltage is used together with current measurements made at the first, second, third, tenth, eleventh and twelfth measurement points MP1, MP2, MP3, MP10, MP11, MP12 in the first variation 10A1 in order to locate the fault in the first, second or third areas A1, A2, A3 or the first and second nodes N1, N2. The same voltage measurement V_{M} is used with current measurements made at all measurement points MP1, MP2, MP3, MP4, MP5, MP5, MP7, MP8, MP9, MP10, MP11, MP12, MP13, MP14, MP15, MP16, MP17, MP18, MP19, MP20, MP21, MP22, MP23 in the second variation 10A2 in order to locate the faults in the first, second, third, fourth, fifth, sixth, seventh, eighth or ninth areas A1, A2, A3, A4, A5, A6, A7, A8, A9 or in the first, second, third, fourth, sixth, eighth, ninth, and eleventh nodes N1, N2, N3, N4, N6, N8, N9, N11. In the first variation of the network 10A1 in FIG. 1, the cost is further reduced, since fewer measurement collecting units are used and possibly also fewer current measurement units. In the second variation of the network 10A2 in FIG. 2 a high precision is obtained in the locating of a fault.

The use of a phase angle between the voltage and current for fault detection is advantageous, since it can identify small fault-currents associated with phase-ground faults. Such fault currents can often be comparable in size with load currents and may therefore be hard to detect in other fault location determining schemes.

It is possible that the fault location determining device does not receive measurements from some of the measurement collecting units. In this case it is possible that it only operates on measurements received from measurement collecting units that are available. It should be realized that the areas may be redefined based on which measurement collecting units that are available.

The power network may also have a number of topologies and the areas may be redefined based on a change of topology. As an example, the power network may comprise a number of switches used to interconnect network elements, such as to interconnect current transmission elements with each other or with transformers. The tenth node N10 in FIG. 2 may as an example be connected to the second end of the ninth current transmission element CTE9 via a switch, when the switch is closed the areas are divided as shown in FIG. 2. However, in case the switch is opened then the seventh area A7 would be split into two different areas, an area A7-1 comprising the ninth current transmission element CTE9 and an area A7-2 comprising the tenth node N10 and the tenth current transmission element CTE10.

Above, the fault location determining arrangement was provided as a fault location determining device 18 comprising a processor performing the fault location determining function. This device may be provided anywhere in or for the power network. As an alternative, the fault location determining device may be distributed, such as over one or more of the measurement collecting units. Thereby, the fault location determining function may be implemented using a number of processors, for instance in one or more of the measurement collecting units, which processors together form the fault location determining arrangement. These measurement collecting units may then cooperate to perform the fault location determining function. The measurement collecting units may then also use peer-to-peer communication.

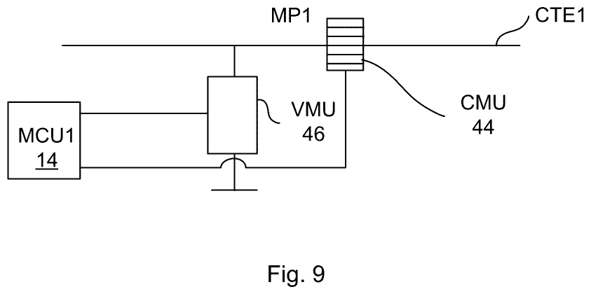

The voltage measurement has been collected by a measurement collecting unit from a voltage measurement unit and this measurement collecting unit also collects current measurements from a number of current measurement units. How this can be realized is schematically shown in FIG. 9 for the first measurement collecting unit MCU1 14 of the first type of power network when the first measurement point MP1 is used for measuring both voltage and current. In this case a current measurement unit CMU 44 and a voltage measurement unit VMU 46 are connected to the first measurement point MP1 of the first current transmission element CTE1. The measurements from these units 44, 46 are collected by the first measurement collecting unit 14 and then transferred to the fault location determining device.

The aspects of the present disclosure have mainly been described above with reference to a few embodiments and examples thereof. However, as is readily appreciated by a person skilled in the art, other embodiments than the ones disclosed above are equally possible within the scope of the invention, as defined by the appended patent claims.

1. A method for determining the location of a fault in a power network, the power network comprising a number of measurement points, a number of network nodes and a number of measurement collecting units, each being provided in a network node, being associated with at least one measurement point at the network node and collecting measurements from said measurement point, the power network being divided into different areas bounded by measurement points from which the measurement collecting units collect measurements, the method being performed in a fault location determining function implemented by a fault location determining arrangement and comprising:
obtaining a voltage V_{O} based on a voltage measurement V_{M} made at a measurement point, which voltage V_{O} is obtained based on processing of the voltage measurement V_{M} made by a measurement collecting unit in the network node associated with the measurement point,
obtaining a number of currents I_{O} based on current measurements made at a plurality of measurement points, which currents are obtained based on processing of the current measurements made by measurement collecting units in network nodes associated with the measurement points and where the current measurements have been made at the same point in time as the voltage measurement,
comparing each current I_{O} with a current threshold I_{Oth},
determining a number of phase angles α based on the voltage V_{O} and all of the currents I_{O}, each phase angle α being a phase angle between the voltage V_{O} and a different current I_{O},
analysing, for each current I_{O}, whether it crosses the threshold I_{Oth} or not and the phase angle α to the voltage V_{O}, and
determining, based on the analysis, if a fault F has occurred in the power network and if a fault has occurred also the area in which it has occurred.

2. The method as claimed in claim 1, wherein a phase angle α represents a direction of the current at the corresponding measurement point.

3. The method as claimed in claim 2, wherein an area is found to have a fault if the direction of the current I_{O} at one or more measurement points at one or more boundaries of the area is above the current threshold I_{Oth} and has a direction into the area and no current at the measurement points at the one or more boundaries of the area is above the current threshold I_{Oth} with a direction out of the area.

4. The method as claimed in claim 1, wherein the power network comprises a number of transformers with neutrals connected to ground according to a grounding scheme and where the current threshold depends on the grounding scheme used.

5. The method as claimed in claim 1, wherein the power network comprises a number of current transmission elements in the group of lines, feeders and buses, where at least two of said measurement points are measurement points at two different current transmission elements.

6. The method as claimed in claim 5, wherein the areas comprise areas of a first type that are bounded by nodes with measurement collecting units and each comprising at least one current transmission element.

7. The method as claimed in claim 6, wherein a node with at least one measurement collecting unit is an area of a second type.

8. A fault location determining arrangement for determining the location of a fault in a power network comprising a number of measurement points, a number of network nodes and a number of measurement collecting units, each being provided in a network node, being associated with at least one measurement point at the network node and collecting measurements from said measurement point, the power network being divided into different areas bounded by measurement points from which the measurement collecting units collect measurements, the fault location determining arrangement including one or more processors operative to implement a fault location determining function including:
obtaining a voltage V_{O} based on a voltage measurement V_{M} made at a measurement point, which voltage V_{O} is obtained based on processing of the voltage measurement V_{M} made by a measurement collecting unit in the network node associated with the measurement point,
obtaining a number of currents I_{O} based on current measurements made at a plurality of measurement points, which currents are obtained based on processing of the current measurements made by measurement collecting units in network nodes associated with the measurement points and where the current measurements have been made at the same point in time as the voltage measurement,
comparing each current I_{O} with a current threshold I_{Oth},
determining a number of phase angles α based on the voltage Vₒ and all of the currents I_{O}, each phase angle α being a phase angle between the voltage V_{O} and a different current I_{O},
analysing, for each current I_{O}, whether it crosses the threshold I_{Oth} or not and the phase angle α to the voltage V_{O}, and
determining, based on the analysis, if a fault F has occurred in the power network and if a fault has occurred also the area in which it has occurred.

9. The fault location determining arrangement as claimed in claim 8, wherein a phase angle α represents a direction of the current at the corresponding measurement point.

10. The fault location determining arrangement as claimed in claim 9, wherein an area is found to have a fault if the direction of the current I_{O} at one or more measurement points at one or more boundaries of the area is above the current threshold I_{Oth} and has a direction into the area and no current at the measurement points at the one or more boundaries of the area is above the current threshold I_{Oth} with a direction out of the area.

11. The fault location determining arrangement as claimed in claim 8, wherein the power network comprises a number of transformers with neutrals connected to ground according to a grounding scheme and where the current threshold depends on the grounding scheme used.

12. The fault location determining arrangement as claimed claim 9, wherein the power network comprises a number of current transmission elements in the group of lines, feeders and buses, where at least two of said measurement points are measurement points at two different current transmission elements.

13. A computer program for determining the location of a fault in a power network, the power network including a number of measurement points, a number of network nodes and a number of measurement collecting units, each being provided in a network node, being associated with at least one measurement point at the network node and collecting measurements from said measurement point, the power network being divided into different areas bounded by measurement points from which the measurement collecting units collect measurements,
the computer program comprising computer program code which when run by one or more processors of a fault location determining arrangement causes the fault location determining arrangement to implement a fault location determining function including:
obtaining a voltage V_{O} based on a voltage measurement V_{M} made at a measurement point, which voltage V_{O} is obtained based on processing of the voltage measurement V_{M} made by a measurement collecting unit in the network node associated with the measurement point,
obtaining a number of currents I_{O} based on current measurements made at a plurality of measurement points, which currents are obtained based on processing of the current measurements made by measurement collecting units in network nodes associated with the measurement points and where the current measurements have been made at the same point in time as the voltage measurement,
comparing each current I_{O} with a current threshold I_{Oth},
determining a number of phase angles α based on the voltage Vₒ and all of the currents I_{O}, each phase angle α being a phase angle between the voltage V_{O} and a different current I_{O},
analysing, for each current I_{O}, whether it crosses the threshold I_{Oth} or not and the phase angle α to the voltage V_{O}, and
determining, based on the analysis, if a fault F has occurred in the power network and if a fault has occurred also the area in which it has occurred.

14. A computer program product for determining the location of a fault in a power network, the computer program product comprising one or more computer-readable storage media with computer program code the power network comprising a number of measurement points, a number of network nodes and a number of measurement collecting units, each being provided in a network node, being associated with at least one measurement point at the network node and collecting measurements from said measurement point, the power network being divided into different areas bounded by measurement points from which the measurement collecting units collect measurements,
the computer program having computer program code which when run by one or more processors of a fault location determining arrangement causes the fault location determining arrangement to implement a fault location determining function including:
obtaining a voltage V_{O} based on a voltage measurement V_{M} made at a measurement point, which voltage V_{O} is obtained based on processing of the voltage measurement V_{M} made by a measurement collecting unit in the network node associated with the measurement point,
obtaining a number of currents I_{O} based on current measurements made at a plurality of measurement points, which currents are obtained based on processing of the current measurements made by measurement collecting units in network nodes associated with the measurement points and where the current measurements have been made at the same point in time as the voltage measurement,
comparing each current I_{O} with a current threshold I_{Oth},
determining a number of phase angles α based on the voltage Vₒ and all of the currents I_{O}, each phase angle α being a phase angle between the voltage V_{O} and a different current I_{O},
analysing, for each current I_{O}, whether it crosses the threshold I_{Oth} or not and the phase angle α to the voltage V_{O}, and
determining, based on the analysis, if a fault F has occurred in the power network and if a fault has occurred also the area in which it has occurred.

15. A power network comprising a fault location determining arrangement, a number of measurement points, a number of network nodes and a number of measurement collecting units, each being provided in a network node, being associated with at least one measurement point at the network node and collecting measurements from said measurement point, the power network being divided into different areas bounded by measurement points from which the measurement collecting units collect measurements, the fault location determining arrangement including one or more processors operative to implement a fault location determining function comprising:
obtaining a voltage V_{O} based on a voltage measurement V_{M} made at a measurement point (MP), which voltage V_{O} is obtained based on processing of the voltage measurement V_{M} made by a measurement collecting unit in the network node (N&) associated with the measurement point,
obtaining a number of currents I_{O} based on current measurements made at a plurality of measurement points, which currents are obtained based on processing of the current measurements made by measurement collecting units in network nodes associated with the measurement points and where the current measurements have been made at the same point in time as the voltage measurement,
comparing each current I_{O} with a current threshold I_{Oth},
determining a number of phase angles α based on the voltage Vₒ and all of the currents I_{O}, each phase angle α being a phase angle between the voltage V_{O} and a different current I_{O},
analysing, for each current I_{O}, whether it crosses the threshold I_{Oth} or not and the phase angle α to the voltage V_{O}, and
determining, based on the analysis, if a fault F has occurred in the power network and if a fault has occurred also the area in which it has occurred.

16. The method as claimed in claim 2, wherein the power network comprises a number of transformers with neutrals connected to ground according to a grounding scheme and where the current threshold depends on the grounding scheme used.

17. The method as claimed in claim 2, wherein the power network comprises a number of current transmission elements in the group of lines, feeders and buses, where at least two of said measurement points are measurement points at two different current transmission elements.

18. The fault location determining arrangement as claimed in claim 9, wherein the power network comprises a number of transformers with neutrals connected to ground according to a grounding scheme and where the current threshold depends on the grounding scheme used.

19. The fault location determining arrangement as claimed in claim 10, wherein the power network comprises a number of current transmission elements in the group of lines, feeders and buses, where at least two of said measurement points are measurement points at two different current transmission elements.
